(19) United States
(12) Patent Application Publication
(10) Pub. No.: US 2014/0139390 A1
(43) Pub. Date: May 22, 2014

(54) ANTENNA APPARATUS

(71) Applicant: Raven Antenna Systems Inc, Dunfermline (GB)

(72) Inventor: Griogair Whyte, Dunfermline (GB)

(73) Assignee: Raven Antenna Systems Inc, Dunfermline (GB)

(21) Appl. No.: 14/087,813

(22) Filed: Nov. 22, 2013

(30) Foreign Application Priority Data
Nov. 22, 2012 (GB) 1221038.1

(51) Int. Cl. H01Q 19/13; H05K 7/00

(52) U.S. Cl. CPC H01Q 19/13; H05K 7/00
USPC 343/840; 361/679.01

(57) ABSTRACT

There is provided satellite transmitted data receiving and/or transmitting apparatus comprising a reflector dish, an elongate member which typically passes through the said reflector dish and at or adjacent to end of the elongate member there is provided data processing components. The elongate member includes at least one portion therealong of a changed shape and the same is formed and located to reduce reflections and hence allow the cross and/or co polarisation patterns to lie within the predetermined radiation pattern envelope limits.

The invention to which this application relates is apparatus for receiving data signals which are transmitted via one or more satellite systems, said apparatus typically including a reflector dish, an arm or elongate member depending from the mounting for the dish and processing components located on the arm and with respect to the dish to receive and process the data signals and then pass the same to further apparatus for onwards processing and the generation of, for example, video and/or audio via a set top box or broadcast data receiver.

The use of this type of apparatus, commonly referred to as satellite dish apparatus, is relatively commonplace, whether it be for use when mounted for, typically domestic, purposes to receive data representative of television and radio programming or for commercial and/or military purposes to allow data signs to be received and/or transmitted.

The apparatus typically includes a shaped sheet metal or composite material reflector “dish” which can be mounted onto a support surface such as a wall or pole via a bracket assembly which is mounted to the rear of the dish. The front surface of the reflector dish is provided to receive satellite broadcast data signals which are transmitted at known frequency ranges. The received signals are directed from the reflector dish towards the processing components mounted on an arm at a spaced distance to the front of the reflector dish. The processing components are typically in the form of a feedhorn, waveguide and a Low Noise Block (LNB). The LNB is provided to allow the required data signals from those that have been received to be passed onto further apparatus for distribution and further processing to allow the data to be provided for the intended end use, such as for the generation of television programmes, radio programmes, auxiliary data, military data, and the like.

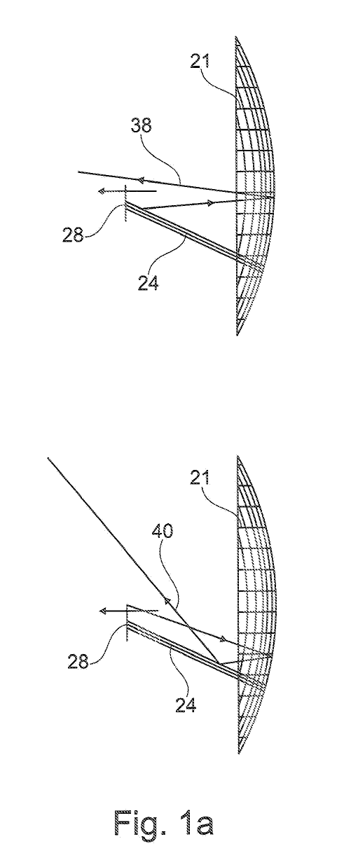

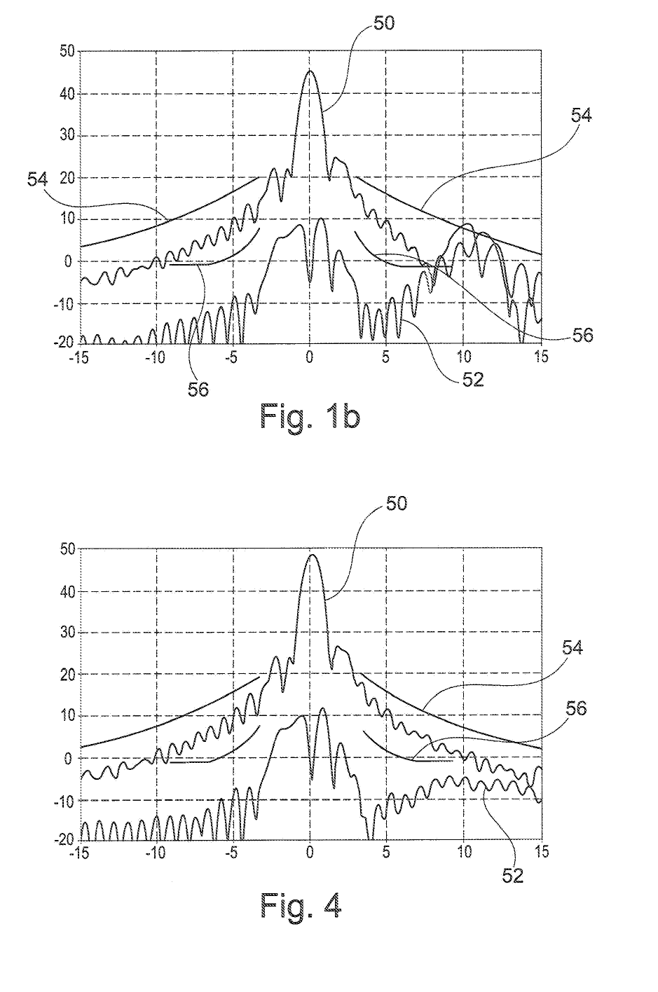

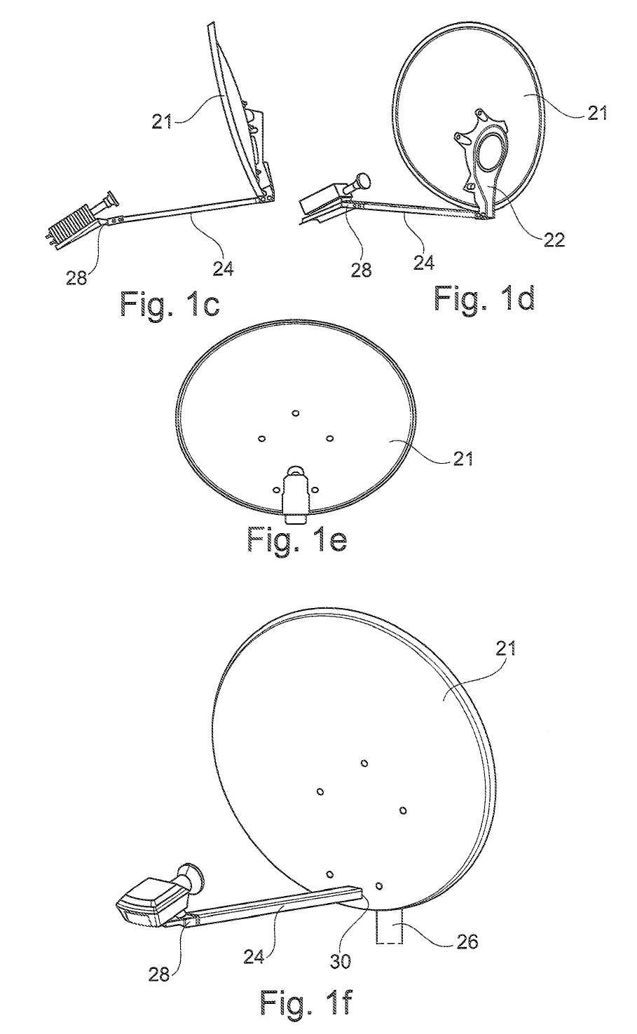

Conventionally, the LNB, wavegeuide and feed horn are located on an elongate arm and the components are provided at, or adjacent to, one end of the member, and the opposing end of the elongate member is located on the mounting bracket to the rear of the reflector dish. This means that the elongate member passes below and to the rear of the reflector dish. This arrangement requires the mounting bracket to be of a significant size which, in turn, causes the apparatus, overall, to be relatively large. An alternative arrangement is to allow the elongate member to pass through an aperture formed in the reflector dish and which is found to improve the performance in terms of mechanical fixing and fitting. However the location of the member passing through the antenna dish can mean that the performance of the antenna apparatus is adversely affected due to the fact that as the member is inserted through the reflector as it is being fitted, so the length of the portion of the member in front of the reflector dish becomes smaller and hence the angle between the reflector dish front surface and the feed horn gets smaller. This results in higher signal reflections which can contribute unwanted energy levels and also increase the possibility of interference with other satellite signal receiving apparatus. Examples of this are illustrated with reference to the FIG. 1a which shows two examples of reflections 38, 40 which occur from the feedhorn illuminating onto the elongate member. This causes the problem illustrated graphically in FIG. 1b in which there is shown a standard elevation cut radiation pattern for antennas of the type shown. The pattern shows the co polarisation pattern 50, and a cross polarisation pattern 52. The co polar radiation pattern envelope limit (RPE) 54 and the cross polar radiation pattern envelope limit (RPE) 56 are shown.

The RPE is generally set to specified limits by regulatory authorities such as the Federal Communications Committee in the USA, or Eutelsat in Europe and the limits are required to be adhered to by the manufacturers and operators of the apparatus in order for the apparatus to be regarded as compatible to the relevant standards and therefore usable. In the FIG. 1b it is shown that both the cross and co polarisation patterns 50,52 exceed their respective RPE limits 54,56 and can therefore lead to the apparatus being declared non compatible

The aim of the present invention is to provided satellite signal receiving and/or transmitting apparatus in which mechanical advantage can still be achieved in terms of the fixing of respective components to form the apparatus while, at the same time, allowing the improved control and passage of the said received and/or transmitted signals.

In a first aspect of the invention there is provided satellite signal receiving and/or transmitting antenna apparatus, said apparatus including a reflector dish, an elongate member with one or more data processing components mounted thereon, said elongate member provided, once installed, in a fixed position with respect to the reflector dish and wherein at least a portion of the length of the elongate member is formed with a shape change therealong.

In one embodiment the shape change portion is positioned to be exposed to the reflective front face of the reflector dish.

In one embodiment the shape change portion is provided along at least that part of the elongate member which is positioned intermediate the said data processing components and the reflective face of the reflector dish.

In one embodiment the shape change is a recessed portion.

In one embodiment the recess portion is formed such as to be substantially V shaped in cross section. In alternative embodiments the surface change portion is any or any combination of a rounded or U shaped recess. In another embodiment the surface change portion may include a series of serrations. In a yet further embodiment the surface change portion may include any or any combination of the features indicated above and/or may include any or any combination of non-uniform width and/or length and/or periodic discontinuities.

Typically the elongate member is located with respect to the reflector dish by passing the elongate member through an aperture formed in the reflector dish, typically the said aperture is located towards the bottom edge of the reflector dish.

Typically the exact dimensions of the recess portion are selected with regard to any, or any combination of, the size of the reflector dish, the characteristics of the signals to be received and/or the signal processing components mounted on the elongate member.

Typically the signal processing components include a receiving horn, a waveguide and an LNB and are mounted at, or adjacent to, an end of the elongate member which is located to the front of the reflector dish.

Typically the end of the elongate member which opposes that end at which the signal processing components are located is engaged with a mounting bracket. Typically the mounting bracket is also used to mount the reflector dish and, in turn the mounting bracket allows the apparatus to be mounted on a support surface such as a wall or pole.

In a further aspect of the invention there is provided antenna apparatus for the reception and/or transmission of data signals via satellite transmission, said apparatus including an elongate member for mounting at least one data processing component at, or adjacent to, one end thereof, and a data signal reflector dish which is located a spaced distance from the data processing component and wherein a recess is formed along at least the portion of said elongate member which is located intermediate the reflector dish and the at least one data processing component.

In a further aspect of the invention there is provided an elongate member for mounting at least one data processing component at or adjacent to one end thereof with respect to a data signal reflector dish which is located a spaced distance from the data processing component and wherein a recess is formed along at least the portion of said elongate member which is located intermediate the reflector dish and the at least one data processing component.

Specific embodiments of the invention are now described with reference to the accompanying drawings; wherein

FIGS. 1a-f illustrate characteristics of conventional satellite data receiving apparatus;

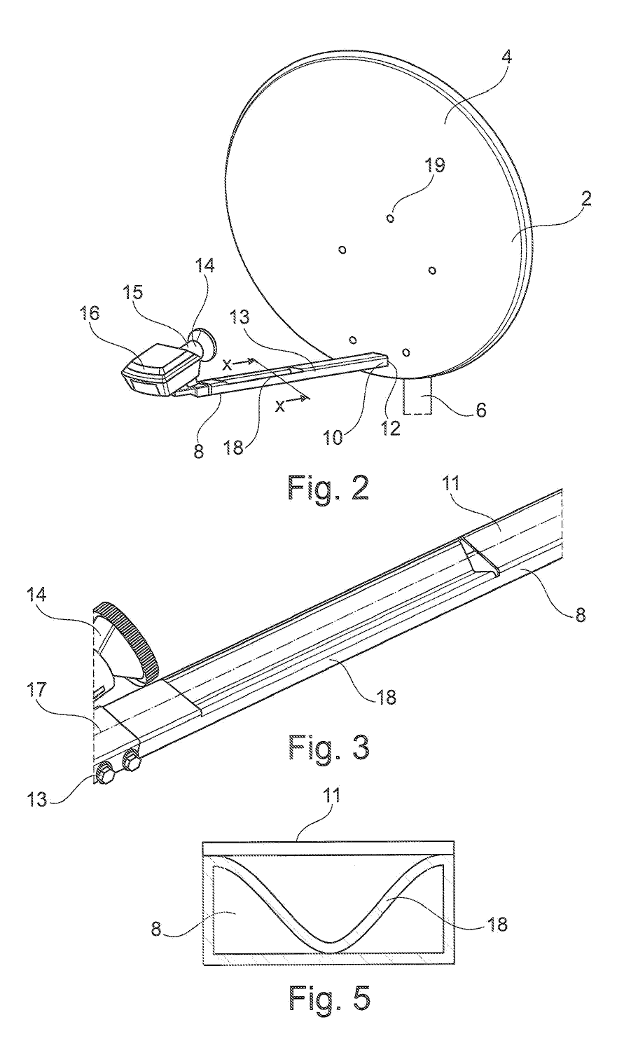

FIG. 2 illustrates one embodiment of satellite data receiving apparatus in accordance with the invention;

FIG. 3 illustrates the elongate member of the apparatus of FIG. 2 in more detail;

FIG. 4 illustrates an antenna system elevation cut radiation pattern for the apparatus of FIGS. 2 and 3,

FIG. 5 illustrates a cross sectional elevation of the elongate member along line XX; and

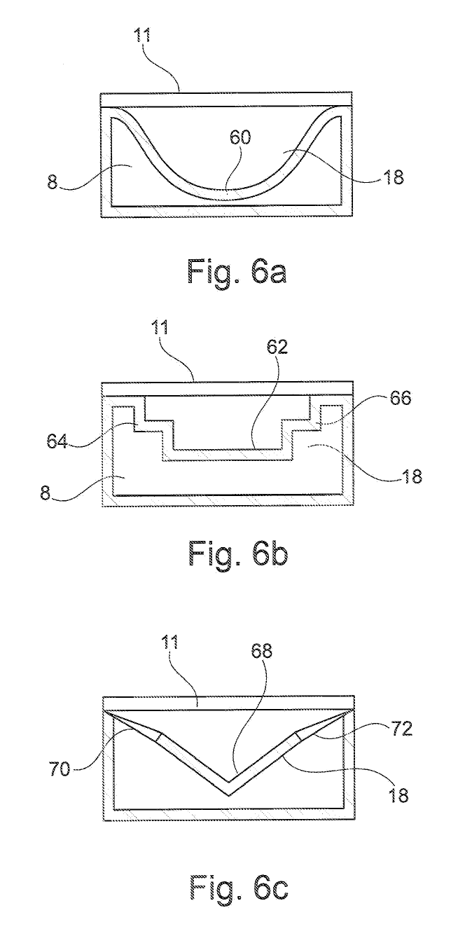

FIGS. 6a-c illustrate cross sectional elevations of further embodiments of the elongate member along line XX.

Referring firstly to FIGS. 1c-f there is shown a first form of conventional parabolic reflector dish antenna apparatus. In both embodiments shown the apparatus comprises a reflector dish 21 which is mounted on a bracket 22 and to which bracket an elongate member 24 is also located. The mounting bracket 24 can then be used to allow the apparatus to be mounted on a support surface such as a wall or pole 26 as shown in FIG. 1f. At the end 28 of the elongate member opposing the bracket end there are mounted data processing components typically including a feedhorn, waveguide and LNB and to which the data signals are reflected from the reflector dish surface as illustrated in FIGS. 1a and b.

In FIGS. 1c-e the elongate member 24 is located below the reflector dish while in FIG. 1f the elongate member 24 passes through an aperture 30 in the dish.

Referring now to the invention of this application as described in FIGS. 2 and 3 there is illustrated satellite data receiving and/or transmitting antenna apparatus 2 in accordance with the invention. The apparatus includes a reflector dish 4 mounted, in this case via a mounting bracket which can be of the type previously described, on a support means in the form of a pole 6 but the same could alternatively be fitted onto a wall using a conventional fitting means. The apparatus includes an elongate member 8, also referred to as a boom arm, which, in this embodiment, close to a first end 10 of the elongate member passes through an aperture 12 in the reflector dish 4. This serves to accurately mechanically locate the elongate member 8 with respect to the reflector dish 4. At the opposing end 13 of the elongate member 8 there is provided data processing means in the form of a receiving or feed horn 14 connected to a waveguide 15 and a Low Noise Block (LNB) which is provided in the housing 16. The receiving or feed horn 14 is positioned on the elongate member 8 with respect to the reflector dish 4 in order to receive data signals which are received by the reflector dish front surface 19 and reflected from the reflector dish towards the receiving or feed horn 14. The required received data signals at the required frequency range or ranges are then passed from the receiving horn through the waveguide and LNB to further apparatus (not shown) such as a broadcast data receiver, via cable connection, in order to allow the data to be further processed in a conventional manner and into the required format.

In accordance with the invention, at least a part of the elongate member 8 includes a portion 18 in which a surface or shape change occurs. This portion 18 extends along the longitudinal axis 17 of the elongate member for at least part of the length thereof. As shown in FIGS. 2 and 3, in the embodiment described, the portion 18 is located intermediate the reflector dish 4 and the data processing components 14,15,16.

In the embodiment shown in FIG. 2-5, the surface change is a recess in the top face 11 of the elongate member (i.e. the face of the elongate member exposed to the reflector dish). In this embodiment the recess is V shaped as shown in FIG. 5 which is a cross section along line XX. However, it should be appreciated that other features and/or shapes may also be included in this surface change portion instead of, or in combination with, the V shaping. FIGS. 6a-c illustrate other possible shapes which can be used in the portion 18 of the elongate arm, with FIG. 6a illustrating a U shaped recess 60, FIG. 6b illustrating a recess 62 with stepped side walls 64,66 and FIG. 6c illustrating a recess 68 which increases in size towards one end as illustrated by the diverging side walls 70,72. The exact dimensions of the recess are selected to suit the particular antenna apparatus with which the elongate member is provided and are selected to minimise reflections that can contribute towards the energy levels of the antenna system exceeding the RPE. For example, the shaped portion may not need to have two end walls and may be formed from one end of the same for the required length or, indeed may be formed along the entire elongate member in one embodiment.

Through the provision of the shaped portion 18 so the number of reflections of the type illustrated in FIG. 1 a are significantly reduced. FIG. 4 illustrates the reflective patterns for the cross and co polarisations achieved through the use of the apparatus in accordance with the invention and the respective RPE limits and uses the same references as used in FIG. 1b. A comparison of FIG. 4 with FIG. 1b shows that in FIG. 4, unlike with FIG. 1b, both the co and cross polarisations patterns are within the specified RPE limit and hence the apparatus meets operational requirements in FIG. 4.

Thus the current invention allows the improved control of the radiating energy levels in elevation when using the apparatus and thus ensuring regulatory compliant antenna apparatus can be provided whilst, at the same time, ensuring that the mechanical advantage of fitting the elongate member through the reflector dish can be obtained. Furthermore the apparatus which is obtained is more compact and rigid.

1. Satellite signal receiving and/or transmitting antenna apparatus, said apparatus including a reflector dish, an elongate member with one or more data processing components mounted thereon, said elongate member provided, once installed, in a fixed position with respect to the reflector dish and wherein at least a portion of the length of the elongate member is formed with a shape change therealong.

2. Apparatus according to claim 1 wherein the shape change portion is positioned to be exposed to the reflective front face of the reflector dish.

3. Apparatus according to claim 1 wherein the shape change portion is provided on at least that part of the elongate member which is positioned intermediate the said data processing components and the reflective face of the reflector dish.

4. Apparatus according to claim 1 wherein the shape change is a recessed portion.

5. Apparatus according to claim 4 wherein the recessed portion is formed such as to be substantially V shaped in cross section.

6. Apparatus according to claim 1 wherein the elongate member passing through an aperture formed in the reflector dish.

7. Apparatus according to claim 6 wherein the aperture is located towards the bottom edge of the reflector dish.

8. Apparatus according to claim 1 wherein the data processing components include a receiving horn, a waveguide and an LNB.

9. Apparatus according to claim 8 wherein the said components a mounted at, or adjacent to, an end of the elongate member which is located to the front of the reflector dish.

10. Apparatus according to claim 9 wherein the end of the elongate member which opposes that end at which the signal processing components are located is engaged with a mounting bracket used to mount the reflector dish and, in turn the mounting bracket allows the apparatus to be mounted on a support surface such as a wall or pole.

11. Antenna apparatus for the reception and/or transmission of data signals via satellite transmission, said apparatus including an elongate member for mounting at least one data processing component at, or adjacent to, one end thereof, and a data signal reflector dish which is located a spaced distance from the data processing component and wherein a recess is formed along at least the portion of said elongate member which is located intermediate the reflector dish and the at least one data processing component.

12. An elongate member for mounting at least one data processing component at or adjacent to one end thereof with respect to a data signal reflector dish which is located a spaced distance from the data processing component and wherein a recess is formed along at least the portion of said elongate member which is located intermediate the reflector dish and the at least one data processing component.
